(19) United States
(12) Patent Application Publication
(10) Pub. No.: US 2016/0268166 A1
(43) Pub. Date: Sep. 15, 2016

(54) SEMICONDUCTOR MEMORY DEVICE AND METHOD OF MANUFACTURING THE SAME

(71) Applicant: Kabushiki Kaisha Toshiba, Minato-ku (JP)

(72) Inventor: Hiroomi Nakajima, Yokkaichi (JP)

(73) Assignee: Kabushiki Kaisha Toshiba, Minato-ku (JP)

(21) Appl. No.: 15/002,799

(22) Filed: Jan. 21, 2016

Related U.S. Application Data
(60) Provisional application No. 62/132,305, filed on Mar. 12, 2015.

(51) Int. Cl. H01L 21/78; H01L 27/115; H01L 23/544

(52) U.S. Cl. CPC H01L 21/78; H01L 23/544; H01L 27/11524; H01L 27/1157; H01L 2223/54453

(57) ABSTRACT

In a method of manufacturing a semiconductor memory device, a stack is formed by alternately stacking an interlayer insulating layer and a first electrically conductive layer. In addition, an insulating layer, a charge accumulation layer, and a semiconductor layer are formed on a side wall of the stack. In addition, a metal layer having a first cutting pattern is formed on the stack. In addition, the stack and the metal layer are cut and divided along a first cutting pattern. The first cutting pattern is provided between a plurality of memory regions, the memory regions are provided for constructing the semiconductor memory device. In addition, the first cutting pattern includes a plurality of cuttings, the cuttings extending in a first direction and being spaced by a predetermined distance in a direction crossing the first direction.

### CROSS-REFERENCE TO RELATED APPLICATIONS

This application is based upon and claims the benefit of U.S. Provisional Patent Application No. 62/132,305, filed on Mar. 12, 2015, the entire contents of which are incorporated herein by reference.

### BACKGROUND

1. Field

The embodiments described below relate to a semiconductor memory device and a method of manufacturing the same.

2. Description of the Related Art

In the field of a NAND flash memory, a stacked (three-dimensional) NAND flash memory has recently drawn attention as a device that can be highly integrated without being restricted by the resolution limit of the lithography technology. This kind of three-dimensional NAND flash memory includes an alternating stack of conductive films and interlayer dielectric films, the conductive films functioning as word-lines and select gate lines, and a semiconductor layer formed to pass through the stack. This semiconductor layer functions as the body of a memory string. The semiconductor layer and the conductive films have a memory film formed therebetween that includes a charge accumulation film.

### BRIEF DESCRIPTION OF THE DRAWINGS

FIG. 1 is a block diagram of a schematic configuration of a non-volatile semiconductor memory device according to a first embodiment.

FIG. 2 is a circuit diagram partially showing the configuration of the non-volatile semiconductor memory device.

FIG. 3 is a schematic perspective view partially showing the configuration of the non-volatile semiconductor memory device.

FIG. 4 is a schematic cross-sectional view partially showing the configuration of the non-volatile semiconductor memory device.

FIG. 5 is a schematic cross-sectional view partially showing the configuration of the non-volatile semiconductor memory device.

FIG. 6 is a schematic plan view partially showing the configuration of the non-volatile semiconductor memory device.

FIG. 7 is a schematic plan view partially showing the configuration of the non-volatile semiconductor memory device.

FIG. 8 is a plan view showing a manufacturing process of the non-volatile semiconductor memory device.

FIG. 9 is a cross-sectional view showing a manufacturing process of the non-volatile semiconductor memory device.

FIG. 10 is a cross-sectional view showing a manufacturing process of the non-volatile semiconductor memory device.

FIG. 11 is a cross-sectional view showing a manufacturing process of the non-volatile semiconductor memory device.

FIG. 12 is a cross-sectional view showing a manufacturing process of the non-volatile semiconductor memory device.

FIG. 13 is a cross-sectional view showing a manufacturing process of the non-volatile semiconductor memory device.

FIG. 14 is a cross-sectional view showing a manufacturing process of the non-volatile semiconductor memory device.

FIG. 15 is a cross-sectional view showing a manufacturing process of the non-volatile semiconductor memory device.

FIG. 16 is a plan view showing a manufacturing process of the non-volatile semiconductor memory device.

FIG. 17 is a plan view showing a manufacturing process of the non-volatile semiconductor memory device.

FIG. 18 is a cross-sectional view showing a manufacturing process of the non-volatile semiconductor memory device.

FIG. 19 is a plan view showing a manufacturing process of a non-volatile semiconductor memory device according to a second embodiment.

FIG. 20 is a plan view showing a manufacturing process of a non-volatile semiconductor memory device according to a third embodiment.

FIG. 21 is a plan view showing a manufacturing process of a non-volatile semiconductor memory device according to a first embodiment.

FIG. 22 is a plan view showing a manufacturing process of a non-volatile semiconductor memory device according to a second embodiment.

FIG. 23 is a plan view showing a manufacturing process of a non-volatile semiconductor memory device according to a third embodiment.

FIG. 24 is a plan view showing a semiconductor wafer having a non-volatile semiconductor memory device according to another embodiment.

FIG. 25 is a schematic cross-sectional view in the allow direction of a surface cutting along the F-F line in FIG. 24.

FIG. 26 is a schematic cross-sectional view showing a non-volatile semiconductor memory device according to another embodiment.

FIG. 27 is a schematic cross-sectional view showing a non-volatile semiconductor memory device according to another embodiment.

FIG. 28 is a schematic cross-sectional view showing a non-volatile semiconductor memory device according to another embodiment.

### DETAILED DESCRIPTION

In a method of manufacturing a semiconductor memory device according to the embodiments described below, an interlayer insulating layer and a first electrically conductive layer are alternately stacked to form a stack. In addition, an insulating layer, a charge accumulation layer, and a semiconductor layer are formed on a side wall of the stack. In addition, a metal layer having a first cutting pattern is formed on the stack. In addition, the stack and the metal layer are cut and divided along the first cutting pattern. The first cutting pattern is provided between a plurality of memory regions provided for constructing the semiconductor memory device. In addition, the first cutting pattern includes a plurality of cuttings extending in a first direction and being spaced by a predetermined distance in a direction crossing the first direction.

Next, the non-volatile semiconductor memory device according to the embodiments will be described in more detail with reference to the drawings.

### First Embodiment

### Configuration

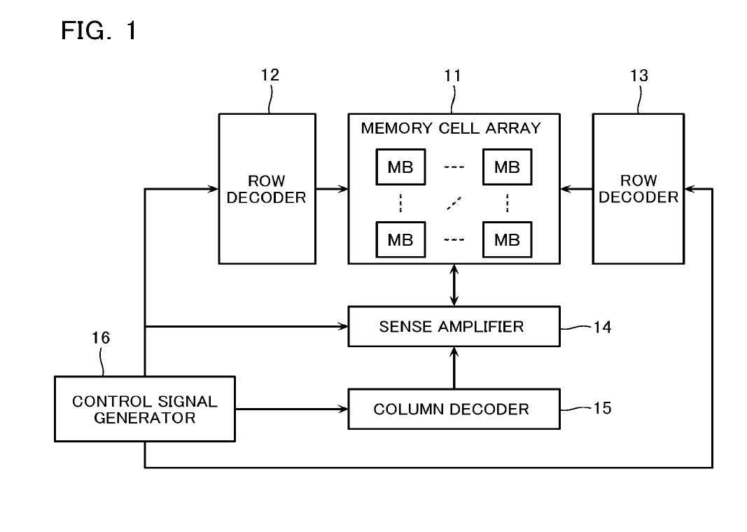

FIG. 1 is a block diagram of a non-volatile semiconductor memory device according to a first embodiment.

The non-volatile semiconductor memory device according to the first embodiment includes, as shown in FIG. 1, a memory cell array 11, row decoders 12 and 13 that control the reading and writing of the memory cell array 11, a sense amplifier 14, a column decoder 15, and a control signal generator 16.

The memory cell array 11 includes a plurality of memory blocks MB. Each memory block MB includes a plurality of memory transistors MTr that store data in a non-volatile manner and are arranged three-dimensionally. Each memory block MB thus forms a minimum erase unit that is collectively erased in the data erase operation. The memory transistors MTr are arranged in a matrix (three-dimensionally) in the row, column, and stacking directions.

The row decoders 12 and 13 decode, as shown in FIG. 1, a captured block address signal or the like and control the memory cell array 11. The sense amplifier 14 reads data from the memory cell array 11. The column decoder 15 decodes the column address signal and controls the sense amplifier 14. The control signal generator 16 increases the reference voltage to generate a high voltage necessary in the writing and erasing. The control signal generator 16 also generates a control signal to control the row decoders 12 and 13, the sense amplifier 14, and the column decoder 15. Note that the row decoders 12 and 13, the sense amplifier 14, the column decoder 15, and the control signal generator 16 forma control circuit that applies a voltage to memory cells in the memory cell array.

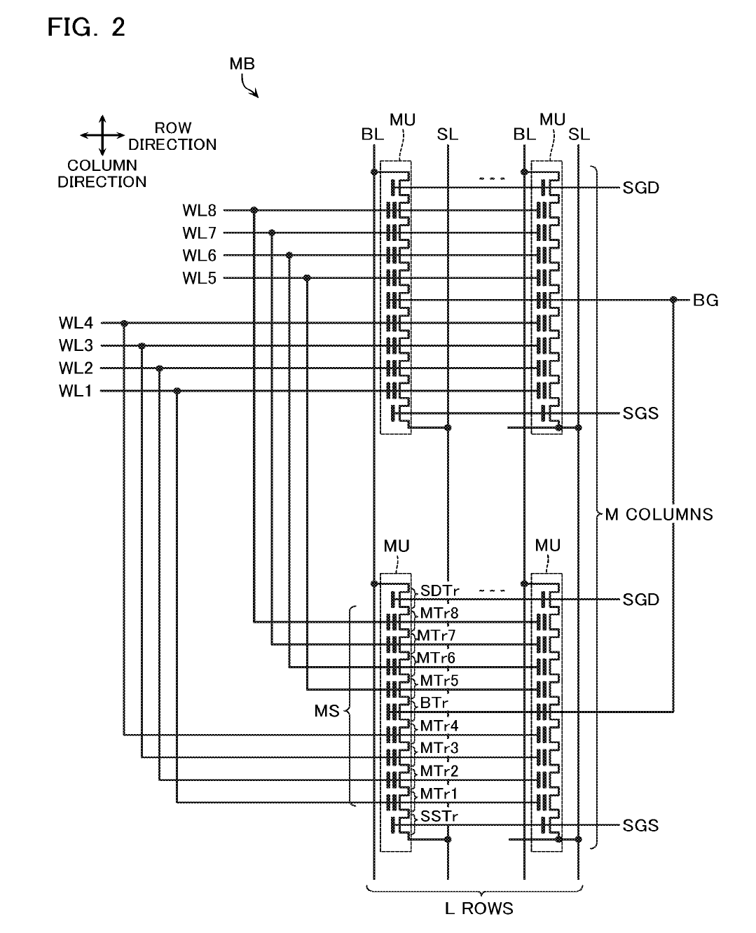

Next, with reference to FIG. 2, the specific configuration of the memory blocks MB will be described. FIG. 2 is a circuit diagram for illustrating the specific configuration of the memory blocks MB. Each memory block MB includes a plurality of bit-lines BL, a plurality of source-lines SL, and a plurality of memory units MU connected to the bit-lines BL and the source-lines SL.

Each memory unit MU forms a NAND flash memory. Each memory unit MU includes a memory string MS, the memory string MS including series-connected memory transistors MTr1 to MTr8 and a back gate transistor BTr, and a source-side select transistor SSTr and a drain-side select transistor SDTr that are connected to the respective ends of the memory string MS. The memory transistors MTr1 to MTr8 accumulate charges in their charge accumulation layers to change their threshold voltage and hold data corresponding to the threshold voltage.

The drain-side select transistors SDTr in the memory units MU arranged in the column direction have drains connected to a common bit-line BL. The source-side select transistors SSTr in the memory units MU arranged in the column direction have sources connected to a common source-line SL. The memory transistors MTr1 to MTr8 have gates connected to respective word-lines WL1 to WL8. The back gate transistors BTr have gates commonly connected to a back gate line BG. The source-side select transistors SSTr have gates connected to source-side select gate lines SGS. The drain-side select transistors SDTr have gates connected to drain-side select gate lines SGD.

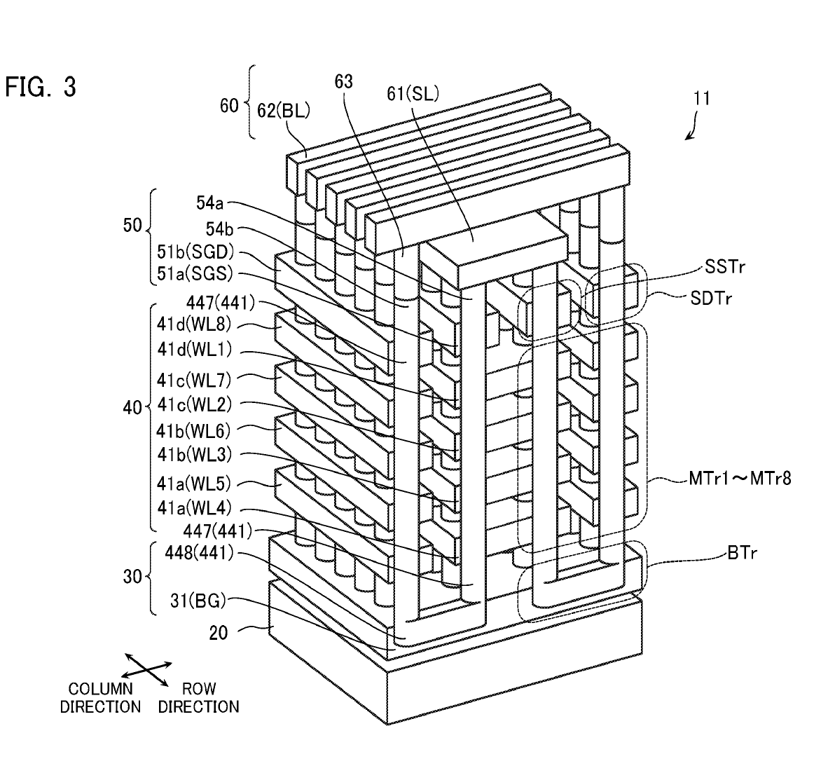

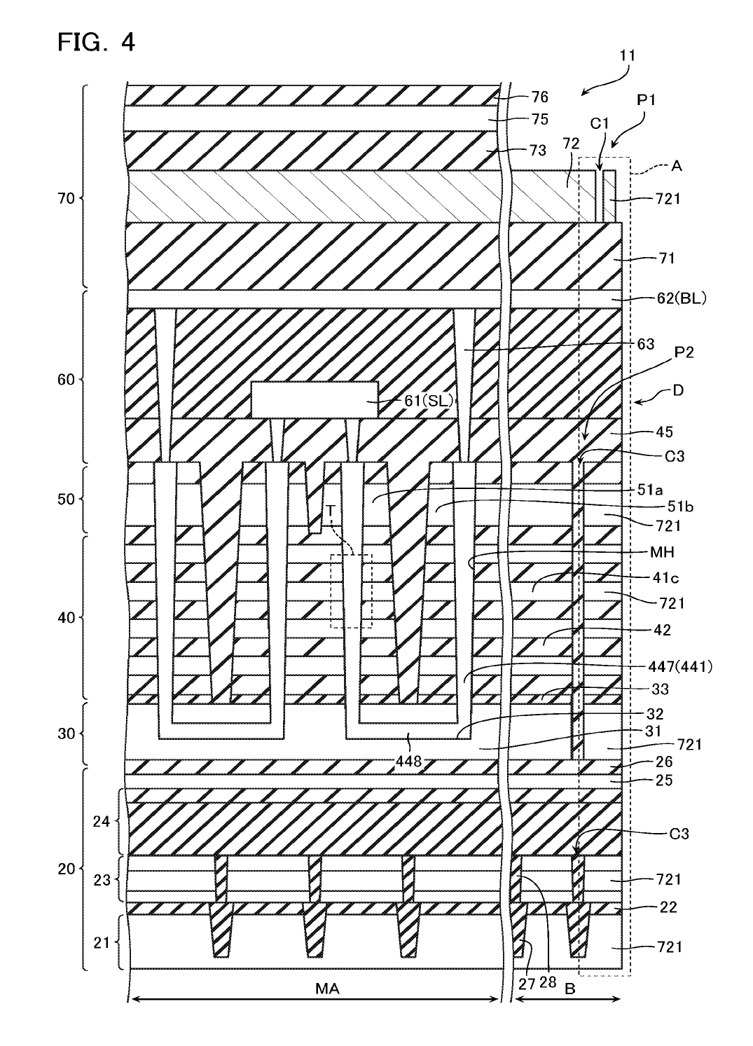

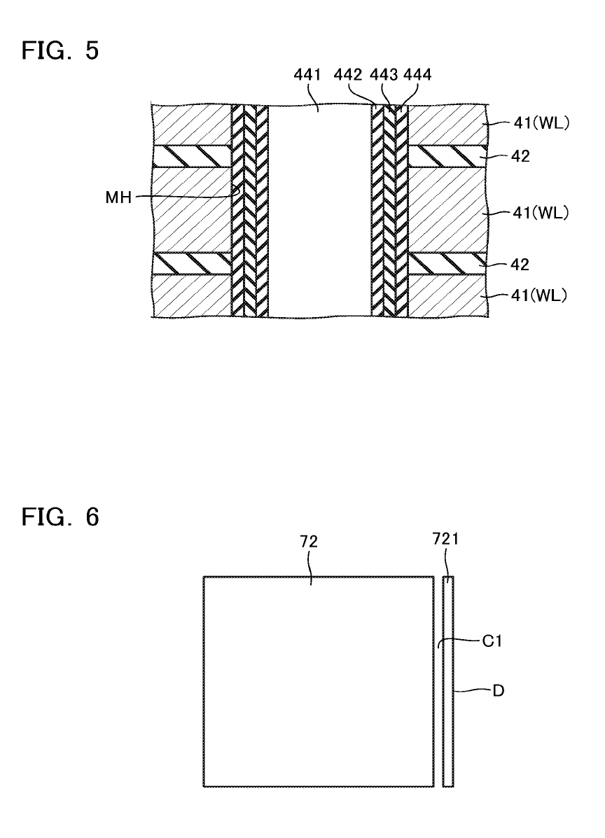

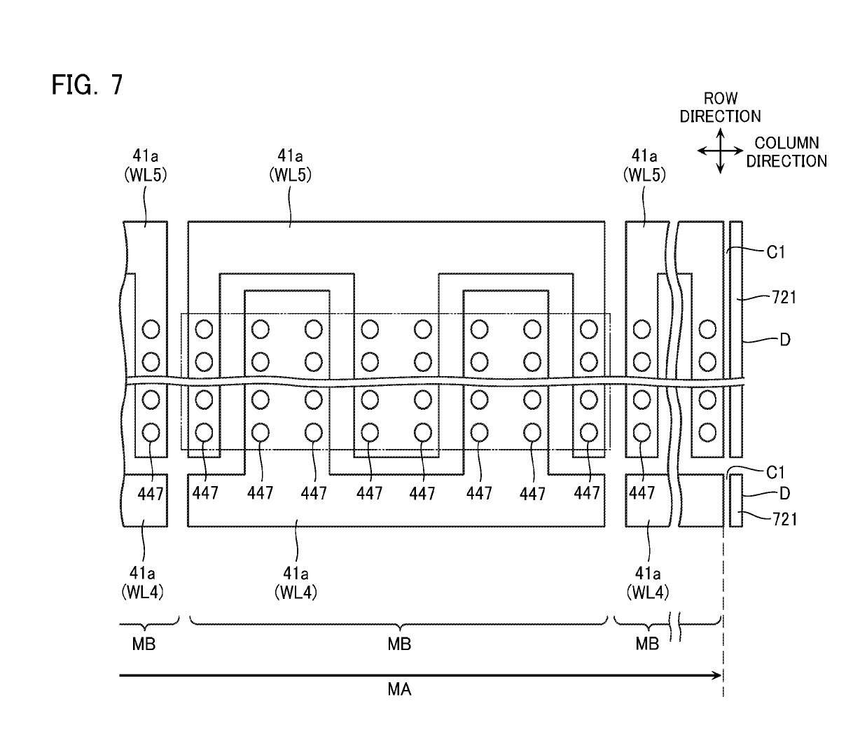

Next, with reference to FIGS. 3 to 7, the structure of the non-volatile semiconductor memory device according to the first embodiment will be described in more detail. FIG. 3 is a perspective view partially showing the memory cell array 11. FIG. 4 is a cross-sectional view partially showing the non-volatile semiconductor memory device. In addition, FIG. 5 is an enlarged view of the portion depicted by T in FIG. 4. FIGS. 6 and 7 are plan views of a portion of the memory cell array 11. FIG. 6 shows a metal layer 72 described below. FIG. 7 shows a word-line conductive layer 41a described below.

Note that although a description is given below with respect to a memory cell array 11 having a Silicon/Oxide/Nitride/Oxide/Silicon structure (SONOS structure), other configurations may also be used such as a memory cell array including a Metal/Oxide/Nitride/Oxide/Silicon structure (MONOS structure) or a Floating Gate structure.

Each memory cell array 11 includes, as shown in FIGS. 3 and 4, a substrate portion 20, a back gate layer 30, a memory layer 40, a select transistor layer 50, a wiring layer 60, and an upper portion wiring layer 70, which are sequentially stacked above the substrate portion 20. The substrate portion 20 comprises a plurality of electric field effect transistors fabricated therein, the transistors configuring the above control circuit. The back gate layer 30 functions as the back gate transistors BTr. The memory layer 40 functions as the memory transistors MTr1 to MTr8. The select transistor layer 50 functions as the drain-side select transistors SDTr and the source-side select transistors SSTr. The wiring layer 60 functions as the source-lines SL and the bit-lines BL. The upper portion wiring layer 70 includes, for example, a metal layer 72 functioning as contact pads or the like.

The substrate portion 20 includes, as shown in FIG. 4, for example, a stack of a semiconductor layer 21, a CMOS gate insulating layer 22, a CMOS gate wiring layer 23, a CMOS interlayer insulating layer 24, a CMOS circuit wiring layer 25, and a CMOS upper portion insulating layer 26 in this order. In addition, as shown in FIG. 4, the upper portion of the semiconductor layer 21 is divided by semiconductor layer insulating layers 27. In addition, as shown in FIG. 4, the CMOS gate wiring layer 23 is divided by CMOS gate wiring layer insulating layers 28.

The semiconductor layer 21 functions as the channels of the transistors included in the control circuit. The CMOS gate insulating layer 22 functions as the gate insulating layers of the transistors included in the control circuit. The CMOS gate wiring layer 23 functions as the gates of the transistors included in the control circuit. The CMOS circuit wiring layer 25 is connected to the semiconductor layer 21 and the CMOS gate wiring layer 23 via not-shown contacts. The CMOS circuit wiring layer 25 functions as wirings that connect each transistor or the like.

The back gate layer 30 includes, as shown in FIG. 3, aback gate conductive layer 31. The back gate conductive layer 31 functions as the back gate lines BG and the gates of the back gate transistors BTr. The back gate conductive layer 31 is formed as a plate extending two-dimensionally in the row and column directions parallel to the substrate portion 20.

The back gate layer 30 includes, as shown in FIG. 4, back gate holes 32. The back gate holes 32 are formed digging the back gate conductive layer 31.

The memory layer 40 is formed, as shown in FIGS. 3 and 4, as an upper layer of the back gate layer 30. The memory layer 40 includes a plurality of (fours in FIGS. 3 and 4) word-line conductive layers 41a to 41d. The word-line conductive layer 41a functions as the word-line WL4 and the gate of the memory transistor MTr4. The word-line conductive layer 41a also functions as the word-line WL5 and the gate of the memory transistor MTr5. Likewise, the word-line conductive layers 41b to 41d function as the word-lines WL2 to WL8 and the gates of the memory transistors MTr2 to MTr8. In addition, as shown in FIG. 4, an interlayer insulating layer 42 is formed between each upper and lower word-line conductive layers 41. Note that the word-line conductive layers 41a to 41d are made of, for example, polysilicon. In addition, the interlayer insulating layer 42 is made of, for example, silicon oxide.

A pair of word-line conductive layers 41a are provided, as shown in FIG. 7, in one memory block MB. The pair of word-line conductive layers 41a are disposed in a comb teeth shape to engage with each other in the row direction when viewed in a top plan view. Columnar semiconductor layers 447 are formed passing through the word-line conductive layers 41a to 41d.

The memory layer 40 includes, as shown in FIG. 4, memory holes MH. The memory holes MH are formed passing though the word-line conductive layers 41a to 41d and the interlayer insulating layer 42. The memory holes MH are formed to be aligned to the vicinities of the column-direction end portions of the back gate holes 32.

In addition, as shown in FIG. 5, the back gate layer 30 and the memory layer 40 include a memory semiconductor layer 441. The memory semiconductor layer 441 functions as the bodies (channels) of the memory strings MS (the memory transistors MTr1 to MTr8) and the back gate transistors BTr.

In addition, as shown in FIG. 5, each of the back gate layer 30 and the memory layer 40 includes a tunnel insulating layer 442 covering the memory semiconductor layer 441, a charge accumulation layer 443 covering the tunnel insulating layer 442, and a block insulating layer 444 covering the charge accumulation layer 443. The charge accumulation layer 443 is configured to be able to accumulate charges.

As shown in FIGS. 4 and 5, the memory semiconductor layer 441, the tunnel insulating layer 442, the charge accumulation layer 443, and the block insulating layer 444 are formed filling in the back gate holes 32 and the memory holes MH. The memory semiconductor layer 441 includes a pair of columnar portions 447 extending perpendicularly to the substrate portion 20 and a coupling portion 448 coupling the pair of columnar portions 447 at their lower ends. The memory semiconductor layer 441 is formed in a U-shape when viewed in the row direction.

The above back gate conductive layer 31 is formed surrounding the side surface of the coupling portion 448. In addition, the word-line conductive layers 41a to 41d are formed surrounding the side surface of the columnar portion 447.

In addition, as shown in FIG. 3, one columnar portion 447 has an upper portion that is surrounded by a source-side conductive layer 51a that functions as the source-side select gate lines SGS. The upper portion functions as the channels of the source-side select transistors SSTr. Likewise, the other columnar portion 447 has an upper portion that is surrounded by a drain-side conductive layer 51b that functions as the drain-side select gate line SGD. The upper portion functions as the channels of the drain-side select transistors SDTr.

In addition, as shown in FIG. 3, the one columnar portion 447 has an upper portion connected to a source-line layer 61 that functions as the source-lines SL. In addition, the other columnar portion 447 has an upper portion connected to, via a plug layer 63, a bit-line layer 62 that functions as the bit-lines BL.

The upper portion wiring layer 70 includes, as shown in FIG. 4, a stack of an insulating layer 71, a metal layer 72 functioning as contact pads or the like, an insulating layer 73 formed above the metal layer 72, a wiring layer 75 formed above the insulating layer 73, and an insulating layer 76 in this order.

In addition, as shown in FIGS. 4, 6, and 7, a stack configuring the memory cell array 11 is divided along surface D by dicing. Thus, surface D is exposed by dicing. In addition, among the layers configuring the memory cell array 11, predetermined layers including electrically conductive layers are divided by cuttings C1 and C3 formed in side end portion A along surface D. The cutting C1 is included in a first cutting pattern P1, and the cutting C3 is included in a second cutting pattern P2. In this embodiment, cutting C1 divides the metal layer 72 and cutting C3 divides at least one of the upper portion of the semiconductor layer 21, the CMOS gate wiring layer 23, the back gate conductive layer 31, the word-line conductive layers 41a to 41d, the interlayer insulating layer 42, the source-side conductive layer 51a, and the drain-side conductive layer 51b. Therefore, remaining portions 721 divided from the layers by cuttings C1 and C3 reside in side end portions A of the divided layers. In the following discussion, a “side end portion” refers to the vicinity of surface D exposed by dicing. As described below in more detail, the remaining portions 721 may expose their side surfaces as surface D exposed by dicing. In addition, the remaining portions 721 are electrically independent from other portions. In addition, because remaining portions 721 are formed by dividing along cuttings C1 and C3 in side end portions A of predetermined layers in which the remaining portions 721 is formed, the portions 721 are formed of the same material as the predetermined layers which are same hierarchy as the remaining portions 721. In addition, FIGS. 6 and 7 show an example where the remaining portions 721 are integrally formed along the side end portions of the word-line conductive layer 41a and the metal layer 72. However, the remaining portions 721 may be a plurality of fragments arranged along the side end portions of the layers.

### [Manufacturing Method]

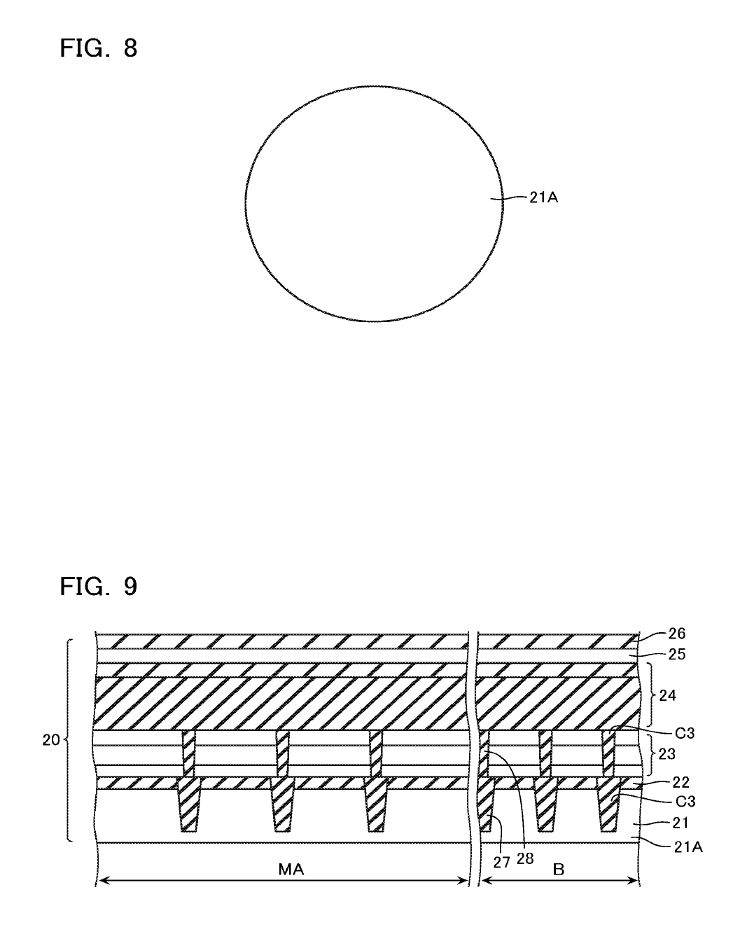

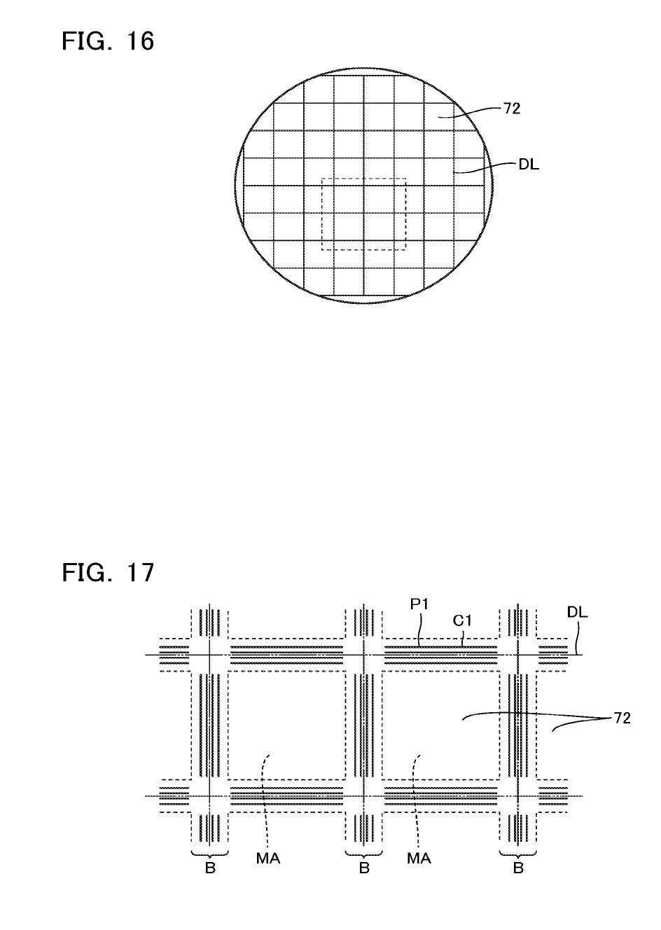

Next, with reference to FIGS. 8 to 18, a method of manufacturing the non-volatile semiconductor memory device according to this embodiment will be described. FIG. 8 and FIG. 16 are schematic plan views for illustrating the manufacturing method. FIG. 17 is an enlarged view of FIG. 16. In addition, FIGS. 9 to 15 and 18 are schematic cross-sectional views for illustrating the manufacturing method. Note that for purposes of illustration, FIGS. 16 and 17 partially omit the configurations.

FIG. 8 is a plan view of a semiconductor substrate 21A. On the semiconductor substrate 21A, a plurality of non-volatile semiconductor memory devices according to this embodiment are manufactured.

As shown in FIG. 9, on the semiconductor substrate 21A, the CMOS gate insulating layer 22 is formed, and then the upper portion of the semiconductor substrate 21A and the CMOS gate insulating layer 22 are divided to form the semiconductor layer 21. Among the divided upper portions of the semiconductor layer 21, portions located in the memory regions MA provided for constructing the non-volatile semiconductor memory device correspond to the channels of the transistors configuring the control circuit. In addition, among the upper portions of the semiconductor layer 21, the portions B located between the memory regions MA are divided parallel to dicing lines DL (see FIG. 16) at a predetermined distance. In other words, among the upper portions of the semiconductor layer 21, in portions B located between the memory regions MA provided for constructing the non-volatile semiconductor memory device, a plurality of third cuttings C3 are formed. The third cuttings C3 extend in a direction parallel to the dicing lines DL and are spaced by a predetermined distance in a direction perpendicular to the dicing lines DL. The third cuttings C3 thus formed are embedded with the semiconductor layer insulating layers 27. Note that in this embodiment, the third cuttings C3 have substantially the same width.

In addition, as shown in FIG. 9, the CMOS gate wiring layer 23 is formed on the CMOS gate insulating layer 22, and then the CMOS gate wiring layer 23 is divided. Among the divided CMOS gate wiring layers 23, portions located in the memory regions MA provided for constructing the non-volatile semiconductor memory device correspond to the gates of the transistors which configure the control circuit. In addition, among the CMOS gate wiring layers 23, portions B located between the memory regions MA are divided at a predetermined distance in parallel with the dicing lines DL (see FIG. 16). In other words, among the CMOS gate wiring layers 23, in portions B located between the memory regions MA provided for constructing the non-volatile semiconductor memory device, a plurality of third cuttings C3 are formed. The third cuttings C3 extend in a direction parallel to the dicing lines DL and are spaced by a predetermined distance in a direction perpendicular to the dicing lines DL. The third cuttings C3 thus formed are embedded with CMOS gate wiring layer insulating layers 28. Note that in this embodiment, the third cuttings C3 have substantially the same width.

In addition, as shown in FIG. 9, on the CMOS gate wiring layer 23, the CMOS interlayer insulating layer 24, the CMOS circuit wiring layer 25, and the CMOS upper portion insulating layer 26 are formed. Thereby the substrate portion 20 is formed. In addition, the CMOS circuit wiring layer 25 is connected to the semiconductor layer 21 and the CMOS gate wiring layer 23 via not-shown contacts. Note, however, that the CMOS circuit wiring layer 25 is not connected to, among the semiconductor layers 21 and the CMOS gate wiring layers 23, portions B located between the memory regions MA provided for constructing the non-volatile semiconductor memory device.

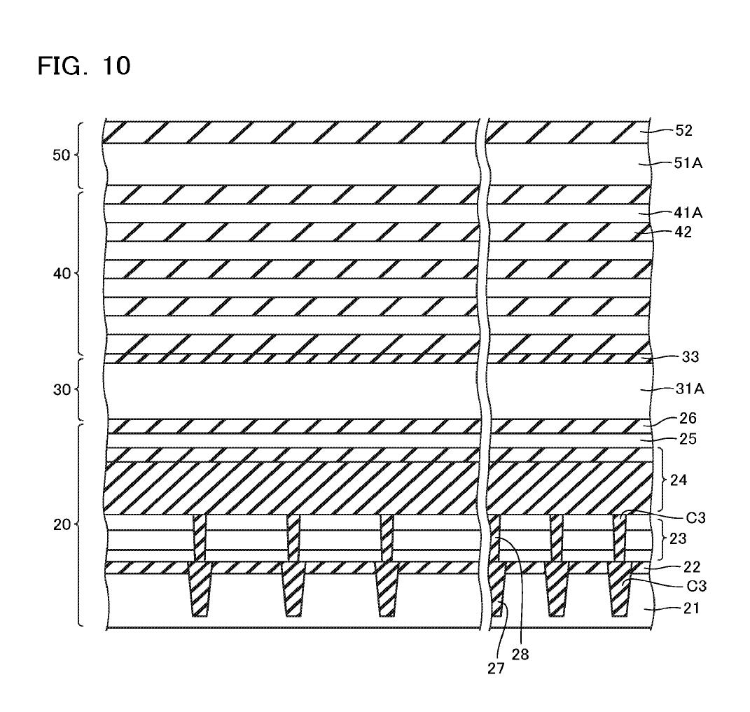

Next, as shown in FIG. 10, a back gate conductive layer 31A and an insulating layer 33 are stacked on the substrate portion 20, and on the insulating layer 33, a plurality of electrically conductive layers 41A forming the word-line conductive layers 41 and a plurality of interlayer insulating layers 42 are stacked to form a stack. In addition, as shown in FIG. 10, an electrically conductive layer 51A and an insulating layer 52 are stacked, the layer 51A forming the source-side conductive layer 51a and the drain-side conductive layer 51b.

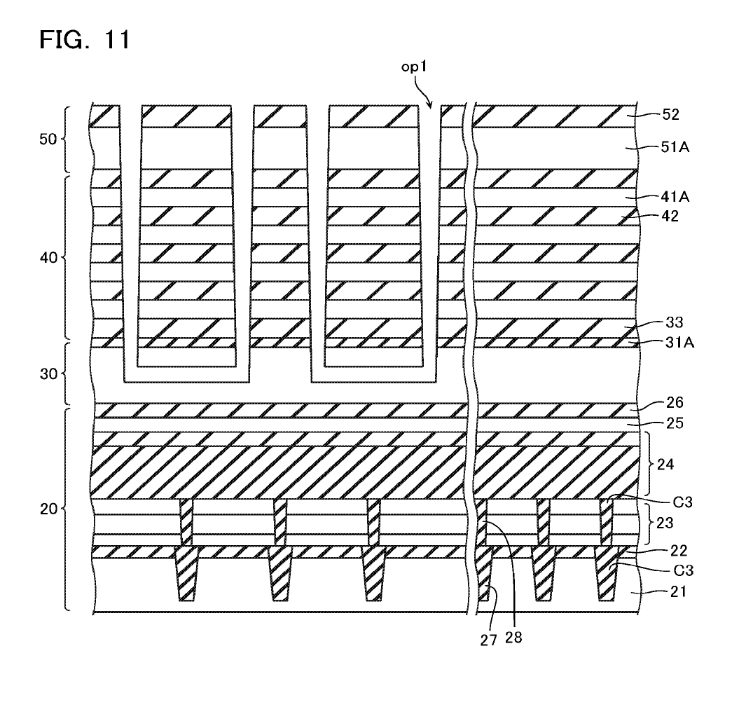

Next, as shown in FIG. 11, openings op1 are formed passing through the insulating layer 33, the electrically conductive layers 41A, the interlayer insulating layers 42, the electrically conductive layer 51A, and the insulating layer 52 in the stacking direction. The openings op1 form the memory holes MH shown in FIG. 4. In addition, as shown in FIG. 11, two adjacent openings op1 communicate at their lower ends.

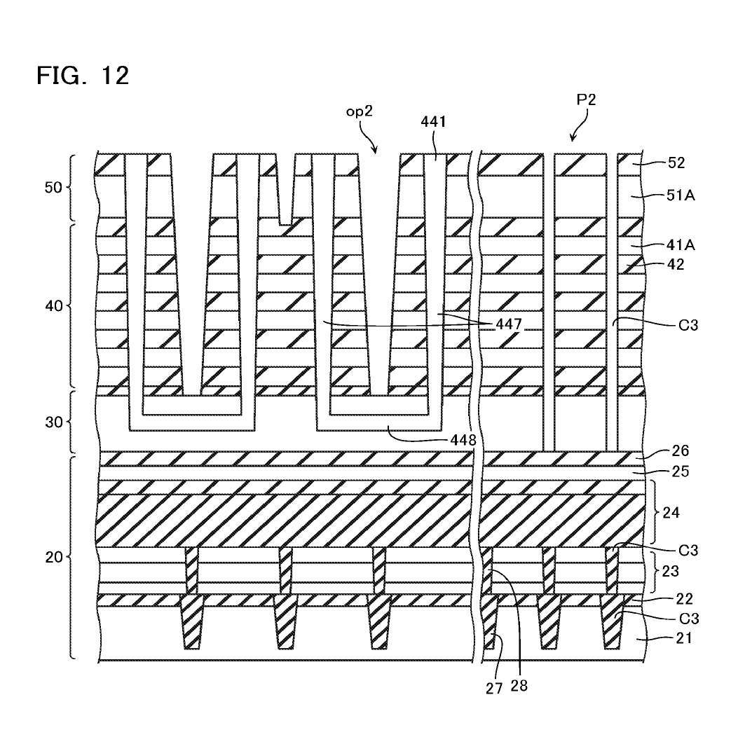

Next, as shown in FIG. 12, a memory semiconductor layer 441 is formed in the opening op1. In so doing, although not shown in FIG. 12, the tunnel insulating layer 442, the charge accumulation layer 443, and the block insulating layer 444 are also formed, which are described with reference to FIG. 5. They fill in the openings op1.

Next, as shown in FIG. 12, the stacked electrically conductive layers 41A and interlayer insulating layers 42 are divided in the column direction. Hereinafter, cuttings (groove) dividing the layers are referred to as openings op2. Each opening op2 is formed between a pair of columnar portions 447, the columnar portions 447 being coupled by the coupling portion 448 at their lower ends. Each opening op2 divides, in the column direction, the electrically conductive layers 41A around a first columnar portion 447 and the electrically conductive layers 41A around a second columnar portion 447. Note that the openings op2 are formed by, for example, means such as RIE (Reactive Ion Etching).

In addition, as shown in FIG. 12, among the stack of the electrically conductive layers 41A and the interlayer insulating layers 42, in a portion B located between the memory regions MA provided for constructing the non-volatile semiconductor memory device, a cutting pattern P2 is formed to divide the stack. In this embodiment, the cutting pattern P2 includes the third cuttings C3, the third cuttings C3 extending in a direction parallel to the dicing lines DL and being spaced by a predetermined distance in a direction perpendicular to the dicing lines DL. Note that in this embodiment, the third cuttings C3 have substantially the same width.

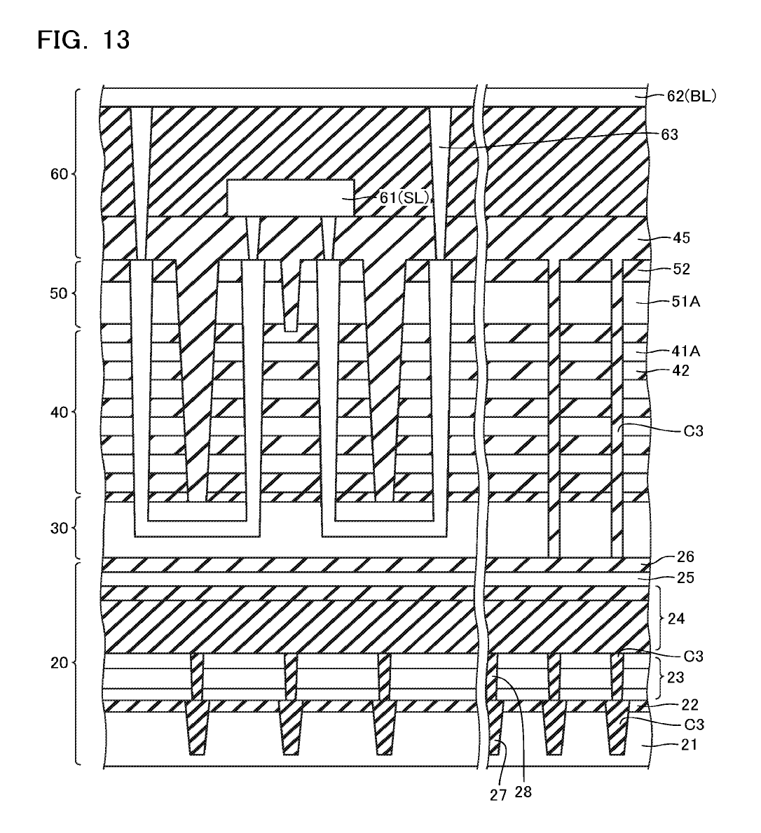

Next, as shown in FIG. 13, the openings op2 and the cuttings forming the cutting pattern P2 are filled with an insulating layer 45. In addition, as shown in FIG. 13, the bit-lines BL and the source-lines SL or the like are formed to form the wiring layer 60.

Next, as shown in FIG. 14, the insulating layer 71, a metal layer forming layer 72A forming the metal layer 72, the insulating layer 73, the wiring layer 75, and the insulating layer 76 are formed. In addition, the insulating layer 73, the wiring layer 75, and the insulating layer 76 are partially removed.

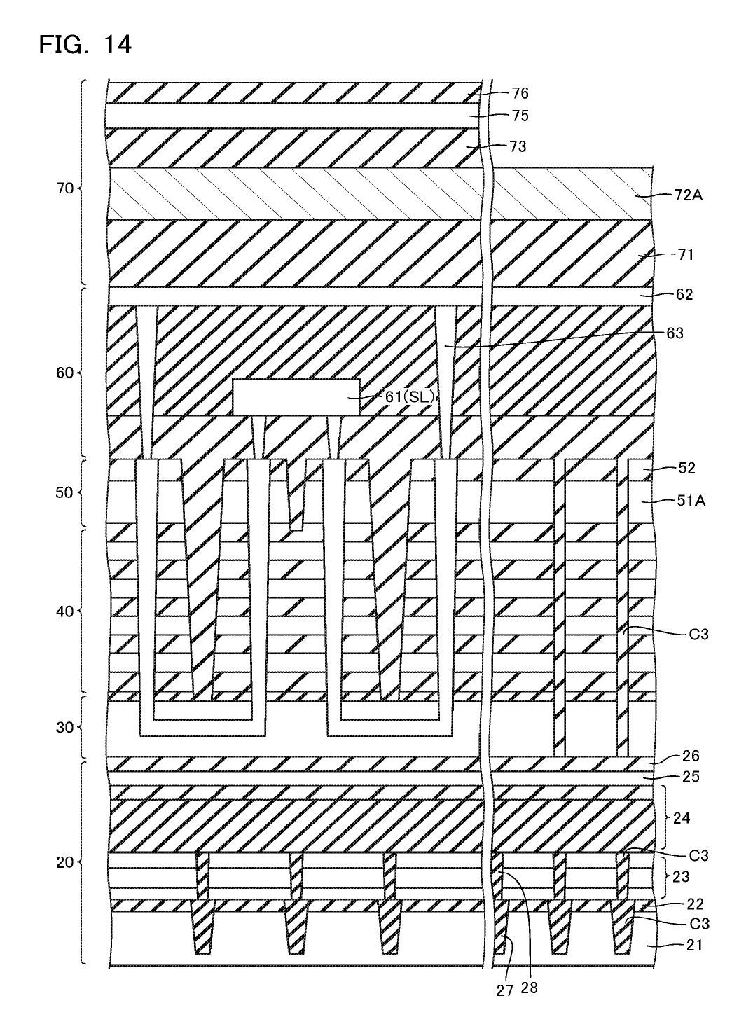

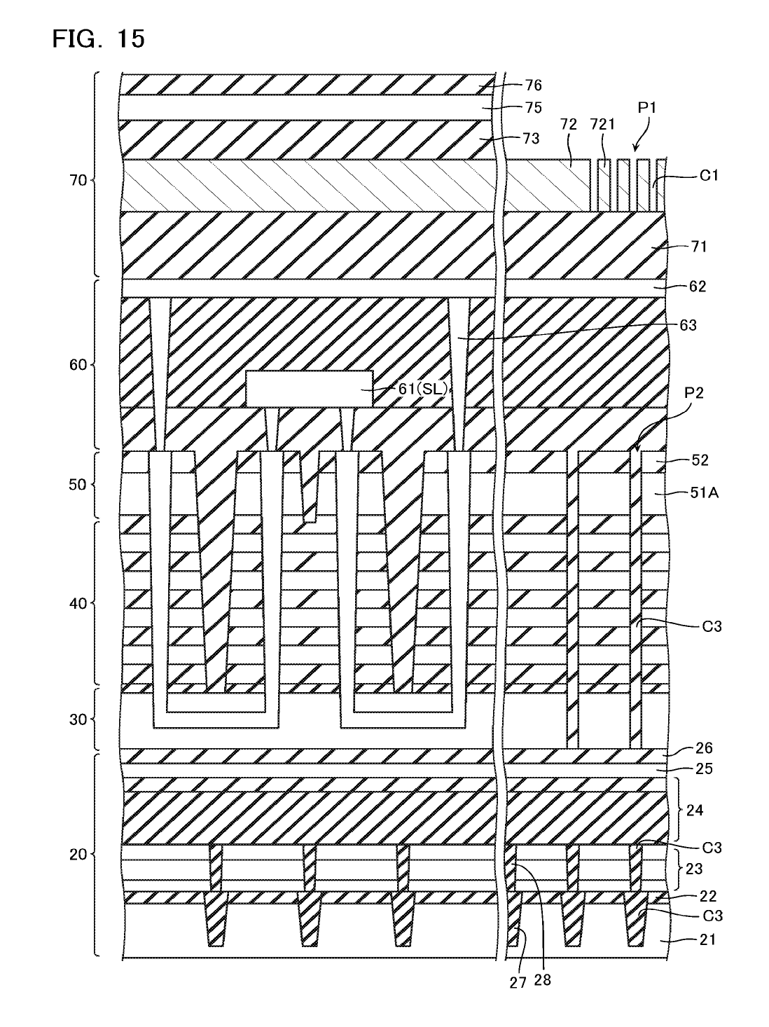

Next, as shown in FIGS. 15 to 17, in a portion of the metal layer forming layer 72A that is located between the memory regions MA provided for constructing the non-volatile semiconductor memory device, a cutting pattern P1 is formed to divide the metal layer forming layer 72A into the metal layers 72. In this embodiment, the cutting pattern P1 includes the first cuttings C1, the first cuttings C1 extending in a direction parallel to the dicing lines DL and being spaced by a predetermined distance in a direction perpendicular to the dicing lines DL. Note that in this embodiment, the first cuttings C1 have substantially the same width. In addition, the cutting pattern P1 may also be formed by, for example, means such as lift off in depositing the metal layer forming layer 72A.

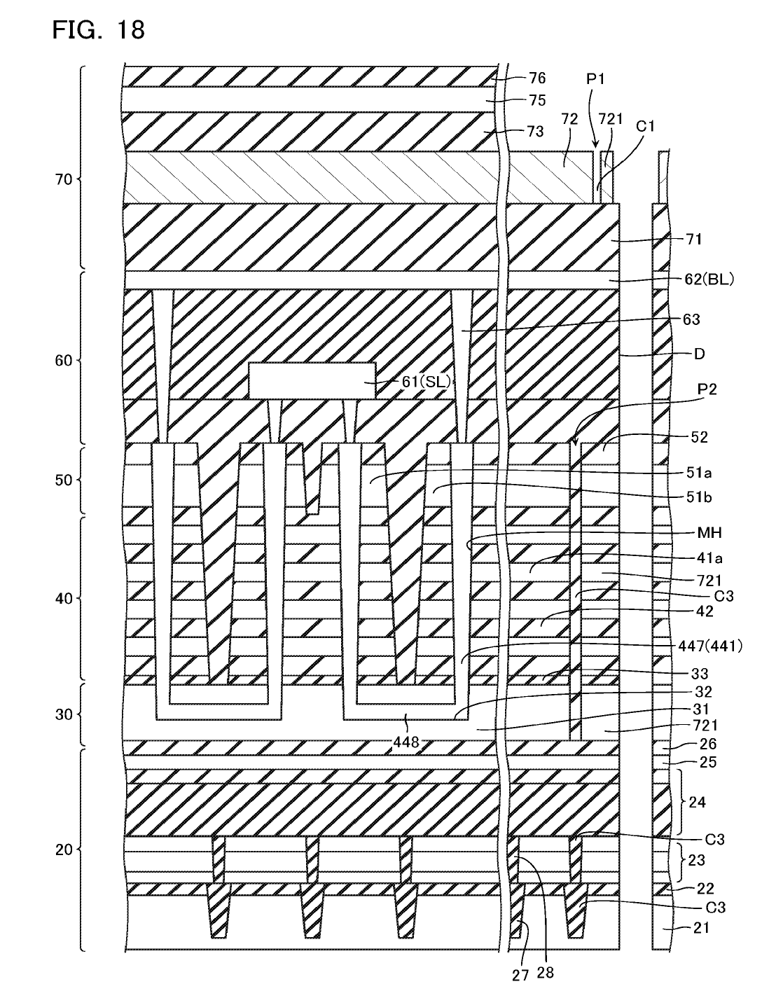

Then, as shown in FIG. 18, cutting and dividing into the semiconductor memory devices along the dicing lines DL are performed to manufacture the semiconductor memory device according to this embodiment.

As shown in FIG. 17, in this embodiment, the cutting pattern P1 is formed along the dicing lines DL in the metal layer 72 which is located to the top layer among the metal layers. Therefore, according to this embodiment, it is possible to prevent chipping and manufacture the non-volatile semiconductor memory device suitably.

Now, as shown in FIG. 17, in this embodiment, the cutting pattern P1 includes the first cuttings C1 extending in a direction parallel to the dicing lines DL and being spaced by a predetermined distance in a direction perpendicular to the dicing lines DL. In this case, depending on an interval of the first cuttings C1 and an aspect of the dicing, the side end portion of the metal layer 72 (near the dicing lines DL) may have the remaining portions 721 formed therein, the remaining portions 721 being described with reference to FIGS. 4 and 6. The remaining portions 721 may remain on only one side of the dicing lines DL or on both sides of the dicing lines DL. In addition, depending on the aspect of the dicing, the remaining portions 721 may not be formed on any sides.

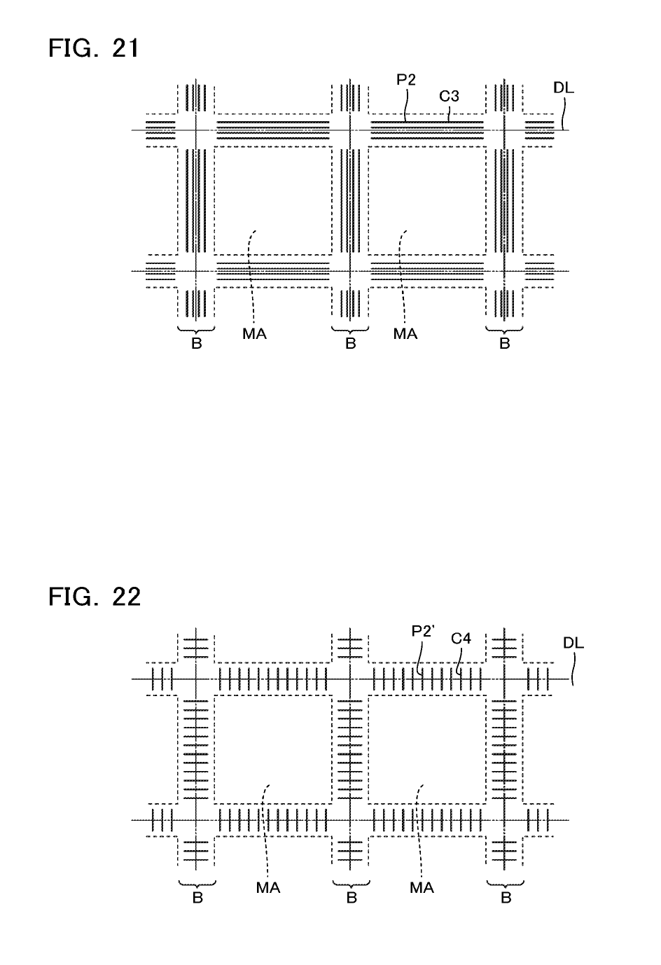

In addition, as shown in FIG. 21, in the non-volatile semiconductor memory device according to this embodiment, cutting patterns P2 along the dicing lines DL is also formed in the upper portion of the semiconductor layer 21, the CMOS gate wiring layer 23, the back gate conductive layer 31, the word-line conductive layers 41a to 41d, and the electrically conductive layer 51A. Therefore, according to this embodiment, it is possible to prevent the chipping more suitably and manufacture the non-volatile semiconductor memory device suitably.

Now, these cutting patterns P2 include, as same as cutting pattern P1, the third cuttings C3 parallel to the dicing lines DL. Therefore, for example, the side end portions of the word-line conductive layers 41a to 41d (near the dicing lines DL) may have the remaining portions 721 remained therein, the remaining portions 721 being described with reference to FIGS. 4 and 7. The remaining portions 721 may remain on only one side of the dicing lines DL or on both sides of the dicing lines DL. In addition, depending on the aspect of the dicing, the remaining portions 721 may not be formed on any sides.

### Second Embodiment

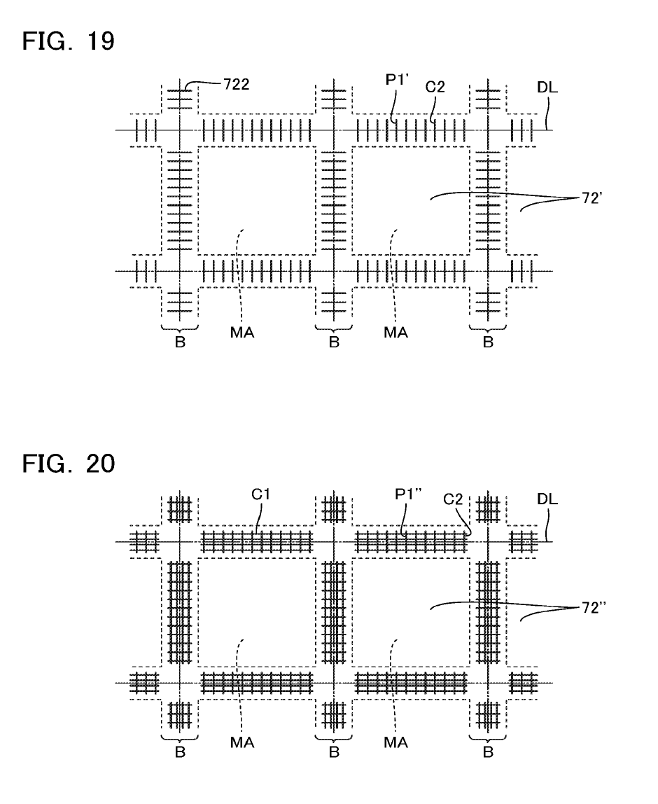

Next, with reference to FIG. 19, a non-volatile semiconductor memory device according to a second embodiment will be described. FIG. 19 is a plan view for illustrating a method of manufacturing the non-volatile semiconductor memory device according to this embodiment. Note that in the following discussion, portions similar to those of the first embodiment are designated with identical reference numerals and their description is omitted here.

As described with reference to FIG. 17, in the first embodiment, cutting pattern P1 formed in the metal layer 72 includes the first cuttings C1, the first cuttings C1 extending in a direction parallel to the dicing lines DL and being spaced by a predetermined distance in a direction perpendicular to the dicing lines DL. In contrast, as shown in FIG. 19, in this embodiment, cutting pattern P1′ formed in a metal layer 72′ includes a plurality of second cuttings C2(722), the second cuttings C2 being spaced by a predetermined distance along the dicing lines DL and extend in a direction perpendicular to the dicing lines DL. Note that these second cuttings C2 are provided between the adjacent ones of the memory regions MA provided for constructing the non-volatile semiconductor memory device. In addition, the second cuttings C2 have substantially the same width. Such an aspect may prevent the chipping and manufacture the non-volatile semiconductor memory device suitably.

Note that when the non-volatile semiconductor memory device is manufactured by the manufacturing method according to this embodiment, after the dicing, the side end portion of the metal layer 72′ or the like (near the dicing lines DL) may have the second cuttings C2 formed therein at a predetermined distance along the side end of the metal layer 72′.

Note that, as shown in FIG. 22, as in the first embodiment, a cutting pattern P2′ including a plurality of fourth cuttings C4 may be formed in the upper portion of the semiconductor layer 21, the CMOS gate wiring layer 23, the back gate conductive layer 31, the word-line conductive layers 41a to 41d, and the electrically conductive layer 51A, the cuttings C4 being spaced by a predetermined distance along the dicing lines DL and extending in a direction perpendicular to the dicing lines DL.

### Third Embodiment

Next, with reference to FIG. 20, a non-volatile semiconductor memory device according to a third embodiment will be described. FIG. 20 is a plan view for illustrating a method of manufacturing the non-volatile semiconductor memory device according to this embodiment. Note that in the following discussion, portions similar to those of the first embodiment are designated with identical reference numerals and their description is omitted here.

As described with reference to FIG. 17, in the first embodiment, cutting pattern P1 formed in the metal layer 72 includes the first cuttings C1, the first cuttings C1 extending in a direction parallel to the dicing lines DL and being spaced by a predetermined distance in a direction perpendicular to the dicing lines. In addition, as shown in FIG. 19, in the second embodiment, the cutting pattern P2′ formed in the metal layer 72′ includes the second cuttings C2, the second cuttings C2 being spaced by a predetermined distance along the dicing lines DL and extending in a direction perpendicular to the dicing lines DL. In contrast, as shown in FIG. 20, in this embodiment, cutting pattern P1″ formed in the metal layer 72″ include the first cuttings C1 that extend in a direction parallel to the dicing line DL and that are spaced by a predetermined distance in a direction perpendicular to the dicing line. Furthermore, cutting pattern P1″ also includes a plurality of second cuttings C2, the second cuttings C2 being formed along the dicing lines DL at a predetermined distance and extending in a direction perpendicular to the dicing lines DL. Note that the first and second cuttings C1 and C2 are provided between the adjacent ones of the memory regions MA provided for constructing the non-volatile semiconductor memory device. In addition, the first and second cuttings C1 and C2 have substantially the same width. Such an aspect may also prevent the chipping and manufacture the non-volatile semiconductor memory device suitably.

In this case, as same as in the first embodiment, the side end portion of the metal layer 72″ (near the dicing lines DL) may have the remaining portions 721 formed therein, the remaining portions 721 being described with reference to FIGS. 4 and 6. In addition, as in the second embodiment, the side end portion of the metal layer 72″ may have cuttings formed therein along the side end of the metal layer 72 at a predetermined distance. In addition, both of the remaining portions 721 and cuttings may be formed.

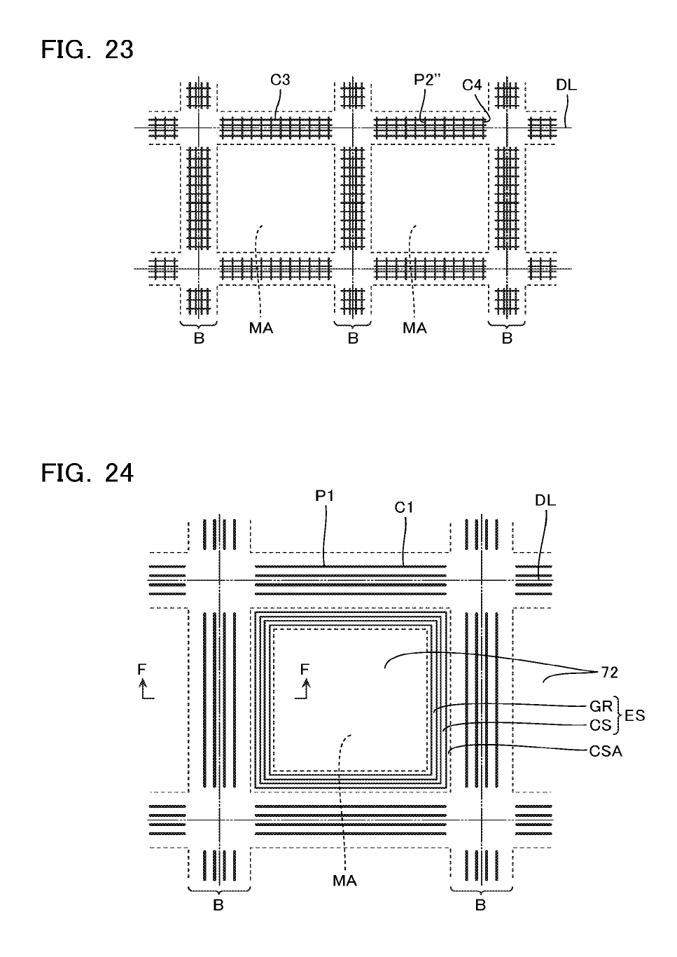

Note that, as shown in FIG. 23, as in the first embodiment, a plurality of cuttings may be formed in the upper portion of the semiconductor layer 21, the CMOS gate wiring layer 23, the back gate conductive layer 31, the word-line conductive layers 41a to 41d, and the electrically conductive layer 51A, the cuttings including the third cuttings C3 that extend in a direction parallel to the dicing lines DL and are spaced by a predetermined distance in a direction perpendicular to the dicing lines and the fourth cuttings C4 that are spaced by a predetermined distance along the dicing lines DL and extend in a direction perpendicular to the dicing lines DL.

### Other Embodiments

Note that the first to third embodiments may provide cuttings only in the metal layer 72, 72′ or 72″ and omit cuttings for other layers. In addition, the first cutting patterns P1, P1′ and P1″ and second cutting patterns P2, P2′ and P2″ according to the embodiments may be used in combination as appropriate. For example, cutting pattern P1 according to the first embodiment may be formed in the metal layer 72 and cutting pattern P2′ according to the second embodiment may be formed in the word-line conductive layers 41a to 41d, or the like.

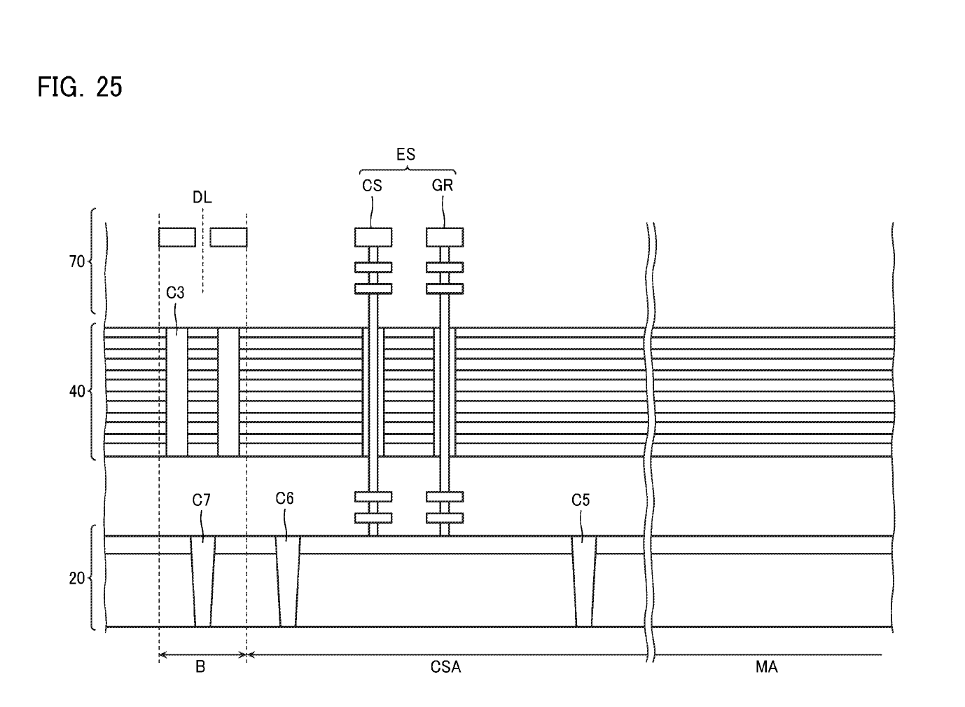

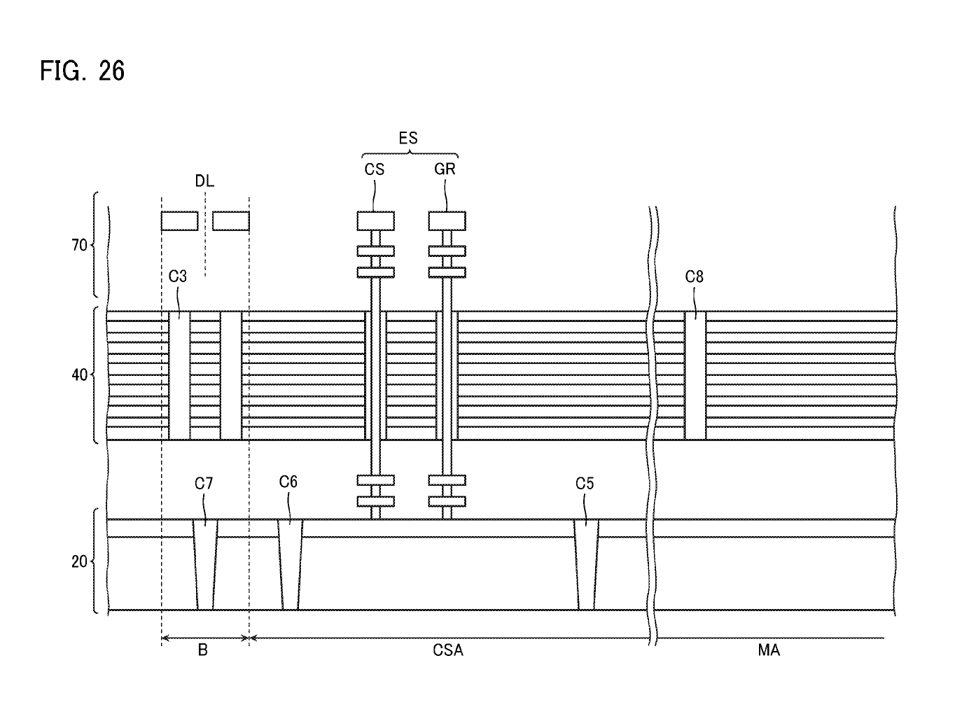

In addition, in the case that a portion B (scribe line region) of a substrate has a slit for edge seal extending along the dicing line DL or a hole and/or a slit for crack prevention and the substrate has a crack stopper region CSA, an example of a positional relation between the crack stopper region CSA and the above described cuttings C3 is as follows. FIG. 24 is a plan view showing a semiconductor wafer before dicing having the non-volatile semiconductor memory device according to another embodiment. FIG. 25 is a schematic cross-sectional view in the allow direction of a surface cutting along the F-F line in FIG. 24. The crack stopper region CSA is provided between the memory region MA and the portion B so as to surround the memory region MA. The crack stopper region CSA includes an annular edge seal ES which surrounds the memory region MA. The edge seal ES has a double structure comprising an outside annular crack stopper CS and an inside annular guard ring GR. The crack stopper CS and the guard ring GR are formed as slits penetrating the upper wiring layer 70 and the memory layer 40 and extending to the substrate 20. The crack stopper CS prevents the wafer from growing a crack to the memory region MA in the dicing process. The guard ring GR functions to stabilize a substrate electrical potential of a semiconductor chip. The crack stopper CS and the guard ring GR may be comprise portions, which are manufactured in a same process of the cuttings C3, and core portions. The core portions may be configured by conductive material as well as the source contact. In addition, element separating layers C5, C6 and C7 are formed in the substrate portion 20 of the crack stopper region CSA and portion B so as to along the edge seal ES and the dicing line DL. The element separating layers C5-C7 may have STI (Shallow Trench Isolation) structure.

FIG. 26 shows a semiconductor wafer further comprises cutting C8 configured by an insulating layer or a slit in the memory layer 40 in the memory region MA of the component described in FIG. 25.

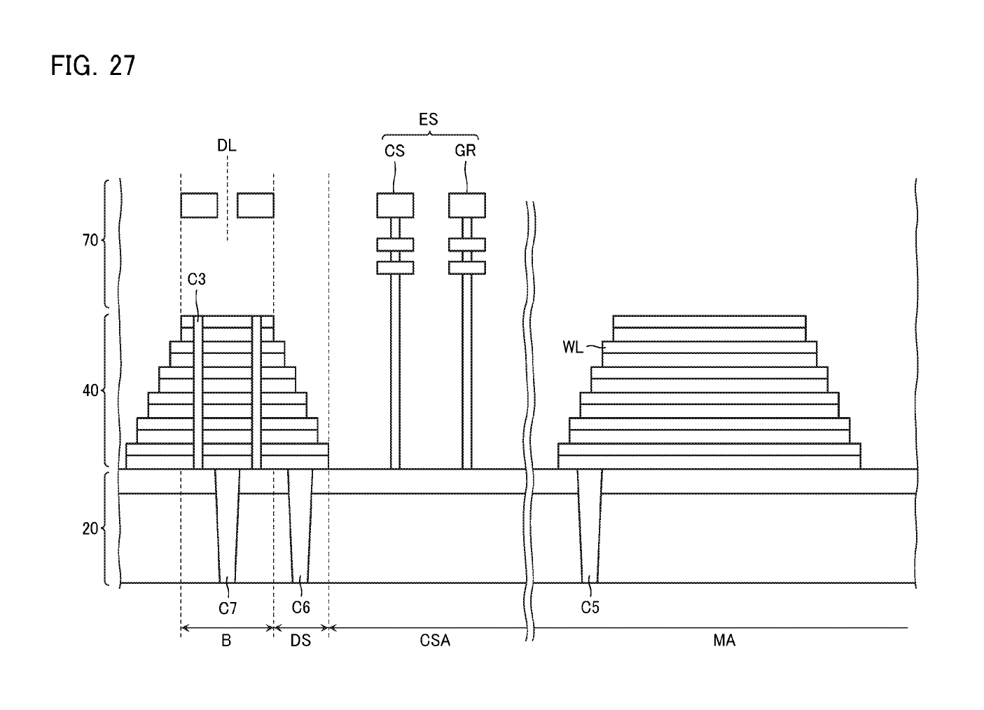

The memory semiconductor layer may be U-shape pipe structure, I-shape column structure, and the like. FIG. 27 shows an example of a semiconductor wafer comprising the memory semiconductor layer having I-shape column structure. In this case, stacked plate shape word lines WL has step shape in its end portions so as to connect each end portion of word line WL in vertical direction. A stack, which is a same structure as the word lines WL, is disposed in the portion B located between the memory regions MA. A dummy step region DS and the crack stopper region CSA are disposed between the memory region MA and the portion B. In this case, as same as in FIGS. 25 and 26, the substrate portion 20 has the element separating layers C5, C6 and C7. The cuttings C3 of the memory layer 40 are disposed at a portion corresponding to the element separating layer C7 in the semiconductor portion 20. In this embodiment, the cuttings C3 may be configured by conductive material as well as the source contact.

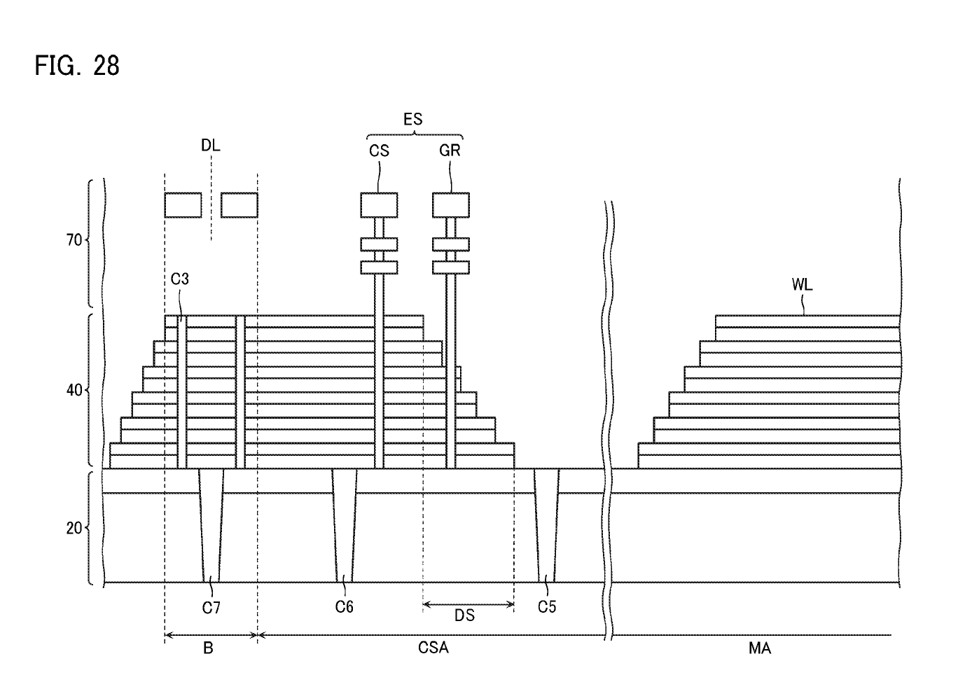

FIG. 28 shows an example that the crack stopper region CSA of the stacked semiconductor memory device includes the dummy step region DS. In this case, at least a portion of the edge seal ES may be formed in the dummy step region DS. This embodiment can reduce the dummy step region DS from a whole space.

### [Others]

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the inventions.

What is claimed is:

1. A method of manufacturing a semiconductor memory device, comprising:
alternately stacking an interlayer insulating layer and a first electrically conductive layer to form a stack;
forming an insulating layer, a charge accumulation layer, and a semiconductor layer on a side wall of the stack;
forming a metal layer having a first cutting pattern on the stack; and
cutting and dividing the stack and the metal layer along the first cutting pattern,
the first cutting pattern being provided between a plurality of memory regions provided for constructing the semiconductor memory device, and
the first cutting pattern comprising a plurality of cuttings, the cuttings extending in a first direction and being spaced by a predetermined distance in a direction crossing the first direction.

2. The method of manufacturing a semiconductor memory device according to claim 1, wherein
the first cutting pattern comprises a plurality of first cuttings, the first cuttings extending in direction parallel to a dicing line and being spaced by a predetermined distance in a direction perpendicular to the dicing line.

3. The method of manufacturing a semiconductor memory device according to claim 1, wherein
the first cutting pattern comprises a plurality of second cuttings, the second cuttings extending in a direction perpendicular to a dicing line and being spaced by a predetermined distance along the dicing line.

4. The method of manufacturing a semiconductor memory device according to claim 1, wherein
the first cutting pattern comprises,
a plurality of first cuttings, the first cuttings extending in a direction parallel to a dicing line and being spaced by a predetermined distance in a direction perpendicular to the dicing line, and
a plurality of second cuttings, the second cuttings extending in a direction perpendicular to the dicing line and being spaced by a predetermined distance along the dicing line.

5. The method of manufacturing a semiconductor memory device according to claim 1, wherein
in cutting the stack and the metal layer, the stack has a second cutting pattern,
the second cutting pattern is provided between the memory regions, and
the second cutting pattern comprises a plurality of cuttings, the cuttings extending in a second direction and being spaced by a predetermined distance in a direction crossing the second direction.

6. The method of manufacturing a semiconductor memory device according to claim 5, wherein
the second direction is the same as the first direction.

7. The method of manufacturing a semiconductor memory device according to claim 5, wherein
the second direction crosses the first direction.

8. The method of manufacturing a semiconductor memory device according to claim 5, wherein
the first cutting pattern comprises a plurality of first cuttings, the first cuttings extending in a direction parallel to a dicing line and being spaced by a predetermined distance in a direction perpendicular to the dicing line.

9. The method of manufacturing a semiconductor memory device according to claim 5, wherein
the first cutting pattern comprises a plurality of second cuttings, the second cuttings extending in a direction perpendicular to a dicing line and being spaced by a predetermined distance along the dicing line.

10. The method of manufacturing a semiconductor memory device according to claim 5, wherein
the first cutting pattern comprises a plurality of first cuttings, the first cuttings extending in a direction parallel to a dicing line and being spaced by a predetermined distance in a direction perpendicular to the dicing line, and
the first cutting pattern comprises a plurality of second cuttings, the second cuttings extending in a direction perpendicular to a dicing line and being spaced by a predetermined distance along the dicing line.

11. The method of manufacturing a semiconductor memory device according to claim 5, wherein
the second cutting pattern comprises a plurality of third cuttings, the third cuttings extending in a direction parallel to a dicing line and being spaced by a predetermined distance in a direction perpendicular to the dicing line.

12. The method of manufacturing a semiconductor memory device according to claim 5, wherein
the second cutting pattern comprises a plurality of fourth cuttings, the fourth cuttings extending in a direction perpendicular to a dicing line and being spaced by a predetermined distance along the dicing line.

13. The method of manufacturing a semiconductor memory device according to claim 5, wherein
the second cutting pattern comprises a plurality of third cuttings, the third cuttings extending in a direction parallel to a dicing line and being spaced by a predetermined distance in a direction perpendicular to the dicing line, and
the second cutting pattern comprises a plurality of fourth cuttings, the fourth cuttings extending in a direction perpendicular to the dicing line and being spaced by a predetermined distance along the dicing line.

14. A semiconductor memory device, comprising:
a stack having an alternately stacked interlayer insulating layer and first electrically conductive layer;
a semiconductor layer opposed to the stack via an insulating layer and a charge accumulation layer; and
a metal layer provided above the stack,
a first remaining portion being provided in a side end portion of the metal layer, the first remaining portion comprising the same material as the metal layer, the first remaining portion being electrically independent from the metal layer.

15. The semiconductor memory device according to claim 14, wherein
a second remaining portion is provided in a side end portion of the first electrically conductive layer, the second remaining portion comprising the same material as the first electrically conductive layer, the second remaining portion being electrically independent from the first electrically conductive layer.

16. The semiconductor memory device according to claim 14, wherein
a plurality of cuttings are provided in a side end portion of the first electrically conductive layer, the cuttings being spaced by a predetermined distance along a side end of the first electrically conductive layer.

17. A semiconductor memory device, comprising:
a stack having an alternately stacked interlayer insulating layer and first electrically conductive layer;
a semiconductor layer opposed to the stack via an insulating layer and a charge accumulation layer; and
a metal layer provided on the stack,
a plurality of cuttings being provided in a side end portion of the metal layer, the cuttings being spaced by a predetermined distance along a side end of the metal layer.

18. The semiconductor memory device according to claim 17, wherein
a remaining portion is provided in a side end portion of the first electrically conductive layer, the remaining portion comprising the same material as the first electrically conductive layer, the remaining portion being electrically independent from the first electrically conductive layer.

19. The semiconductor memory device according to claim 17, wherein
a plurality of cuttings are provided in a side end portion of the first electrically conductive layer, the cuttings being spaced by a predetermined distance along a side end of the first electrically conductive layer.

20. A semiconductor wafer having a semiconductor memory device, comprising:
a substrate,
a stack disposed above the substrate and having an alternately stacked interlayer insulating layer and first electrically conductive layer;
a semiconductor layer opposed to the stack via an insulating layer and a charge accumulation layer; and
a wiring layer provided on the stack,
the substrate having a slit extending in a direction parallel to a dicing line,
the stack having a plurality of cuttings extending in a direction parallel to the dicing line.
